(19) United States
(12) Patent Application Publication
(10) Pub. No.: US 2024/0079215 A1
(43) Pub. Date: Mar. 7, 2024

(54) SUBSTRATE PROCESSING APPARATUS

(71) Applicant: Tokyo Electron Limited, Tokyo (JP)

(72) Inventors: Tetsuma YAGUCHI, Kurokawa-gun (JP); Masanori ASAHARA, Kurokawa-gun (JP)

(73) Assignee: Tokyo Electron Limited, Tokyo (JP)

(21) Appl. No.: 18/459,151

(22) Filed: Aug. 31, 2023

(30) Foreign Application Priority Data
Sep. 5, 2022 (JP) 2022-140722

(51) Int. Cl. H01J 37/32

(52) U.S. Cl. CPC H01J 37/32449; H01J 37/32715; H01J 37/32091

(57) ABSTRACT

A disclosed substrate processing apparatus includes a processing chamber, a substrate support stage. The substrate support provides at least one recess. The at least one recess opens downward. The at least one supply pipe is configured to supply a heat transfer medium to the at least one recess. The at least one partition forms at least one space together with the substrate support stage. The at least one space include the at least one recess. The at least one collection pipe is configured to collect the heat transfer medium from the at least one space. The at least one flow rate adjusting valve that is connected to the at least one supply pipe. The controller is configured to control the at least one flow rate adjusting valve to adjust a flow rate of the heat transfer medium supplied to the at least one supply pipe.

### CROSS-REFERENCE TO RELATED APPLICATIONS

This application is based on and claims the benefit of priority from Japanese Patent Application No. 2022-140722 filed on Sep. 5, 2022, the entire contents of which are incorporated herein by reference.

### FIELD

Exemplary embodiments of the present disclosure relate to a substrate processing apparatus.

### BACKGROUND

A substrate processing apparatus may include a substrate support stage capable of controlling the temperature of a substrate placed on the substrate support stage. In a substrate processing apparatus described in Japanese Unexamined Patent Publication No. 2016-12593 the temperature of a substrate is controlled by supplying a heat transfer medium prepared at a first temperature and a heat transfer medium prepared at a second temperature higher than the first temperature to a substrate support stage.

### SUMMARY

In an exemplary embodiment, a substrate processing apparatus is provided. The substrate processing apparatus includes a processing chamber, a substrate support stage, at least one supply pipe, at least one partition, at least one collection pipe, at least one flow rate adjusting valve, and a controller. The substrate support stage is disposed in the processing chamber. The substrate support includes an upper surface and a lower surface. The upper surface supports a substrate placed thereon. The lower surface is on a side opposite to the upper surface. The substrate support provides at least one recess. The at least one recess opens downward. The at least one supply pipe includes an opening end. The opening end opens upward in the at least one recess. The at least one supply pipe is configured to supply a heat transfer medium to the at least one recess. The at least one partition forms at least one space together with the substrate support stage. The at least one space include the at least one recess. The at least one collection pipe is configured to collect the heat transfer medium from the at least one space. The at least one flow rate adjusting valve that is connected to the at least one supply pipe. The controller is configured to control the at least one flow rate adjusting valve to adjust a flow rate of the heat transfer medium supplied to the at least one supply pipe.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a diagram for describing a configuration example of a plasma processing system according to an exemplary embodiment.

FIG. 2 is a diagram for describing a configuration example of a capacitively-coupled plasma processing apparatus according to the exemplary embodiment.

FIG. 3 is an enlarged cross-sectional view of a portion of a substrate support stage according to the exemplary embodiment.

FIG. 4A is a perspective view of a base according to the exemplary embodiment, and FIG. 4B is a partially-broken perspective view of the base according to the exemplary embodiment.

FIG. 5 is an exploded perspective view schematically illustrating the base and a heat exchanger according to the exemplary embodiment.

FIG. 6 is a perspective view of the heat exchanger according to the exemplary embodiment.

FIG. 7A is a plan view of a cell portion of the heat exchanger as an example, and FIG. 7B is a perspective view of the cell portion of the example heat exchanger as the example.

FIG. 8 is a diagram schematically illustrating a circulation supply system of a heat transfer medium in the substrate processing apparatus according to the exemplary embodiment.

FIG. 9 is a diagram schematically illustrating a circulation supply system of a heat transfer medium in a substrate processing apparatus according to another exemplary embodiment.

FIG. 10A is a graph showing an example of a relationship between time and a flow rate of the heat transfer medium, and FIG. 10B is a graph showing an example of a relationship between the time and a temperature of a substrate.

FIG. 11 is a diagram schematically illustrating a circulation supply system of a heat transfer medium in a substrate processing apparatus according to still another exemplary embodiment.

FIG. 12 is an enlarged cross-sectional view of a portion of a substrate support stage according to still another exemplary embodiment.

### DETAILED DESCRIPTION

Hereinafter, various exemplary embodiments will be described.

In an exemplary embodiment, a substrate processing apparatus is provided. The substrate processing apparatus includes a processing chamber, a substrate support stage, at least one supply pipe, at least one partition, at least one collection pipe, at least one flow rate adjusting valve, and a controller. The substrate support stage is disposed in the processing chamber. The substrate support includes an upper surface and a lower surface. The upper surface supports a substrate placed thereon. The lower surface is a surface on a side opposite to the upper surface. The substrate support provides at least one recess. The at least one recess opens downward. The at least one supply pipe includes an opening end. The opening end opens upward in the at least one recess. The at least one supply pipe is configured to supply a heat transfer medium to the at least one recess. The at least one partition forms at least one space together with the substrate support stage. The at least one space include the at least one recess. The at least one collection pipe is configured to collect the heat transfer medium from the at least one space. The at least one flow rate adjusting valve that is connected to the at least one supply pipe. The controller is configured to control the at least one flow rate adjusting valve to adjust a flow rate of the heat transfer medium supplied to the at least one supply pipe.

In the above embodiment, the flow velocity of a heat transfer medium supplied to at least one recess of a substrate support stage is adjusted by adjusting the flow rate of the heat transfer medium supplied to at least one supply pipe. The temperature of a substrate on the substrate support stage changes in accordance with the flow velocity of the heat transfer medium supplied to at least one recess. Therefore, according to the above embodiment, it is possible to control the temperature of the substrate.

In the exemplary embodiment, the substrate support stage may include a plurality of zones. The plurality of zones may provide a plurality of recesses as the at least one recess. The plurality of zones may each include one or more of the plurality of recesses. The substrate processing apparatus may include a plurality of supply pipes as the at least one supply pipe. The opening end of each of the plurality of supply pipes may be disposed in the corresponding recess among the plurality of recesses. The substrate processing apparatus may include a plurality of partitions as the at least one partition. The plurality of partitions may form a plurality of spaces together with the substrate support stage. The plurality of spaces may respectively include the plurality of recesses. The substrate processing apparatus may include a plurality of collection pipes as the at least one collection pipe. The plurality of collection pipes may be respectively connected to the plurality of spaces. The substrate processing apparatus may include a plurality of flow rate adjusting valves as the at least one flow rate adjusting valve. The substrate processing apparatus may include a plurality of common supply pipes and a plurality of common collection pipes. The plurality of common supply pipes may each connected to one or more supply pipes through the corresponding flow rate adjusting valve among the plurality of flow rate adjusting valves. The one or more supply pipes may be for the corresponding zone of the substrate support stage, among the plurality of supply pipes. The plurality of common collection pipes may each be connected to one or more collection pipes. The plurality of common collection pipes may be for the corresponding zone of the substrate support stage among the plurality of collection pipes. In the present embodiment, the flow rate of the heat transfer medium supplied to each of a plurality of zones of the substrate support stage is adjusted by a corresponding flow rate adjusting valve among a plurality of flow rate adjusting valves. Therefore, according to the present embodiment, it is possible to individually control temperatures of a plurality of regions of the substrate located on each of the plurality of zones.

In the exemplary embodiment, the substrate processing apparatus may include a common supply line, a common collection line and a bypass flow rate adjusting valve. The common supply line may be connected to the plurality of common supply pipes. The common collection line may be connected to the plurality of common collection pipes. The bypass flow rate adjusting valve may be connected between the common supply line and the common collection line. Each of the plurality of flow rate adjusting valves may be configured to adjust the flow rate of the heat transfer medium supplied to the one or more supply pipes by adjusting an opening degree thereof. The one or more supply pipes may be for the corresponding zone of the substrate support stage among the plurality of supply pipes. The controller may be configured to control the opening degree of each of the plurality of flow rate adjusting valves, and control an opening degree of the bypass flow rate adjusting valve to maintain a total flow rate of the heat transfer medium supplied to the plurality of common supply pipes and the heat transfer medium bypassed to the common collection line from the common supply line. In the present embodiment, even though the flow rate of the heat transfer medium supplied to one zone among the plurality of zones is changed, the flow rate of the heat transfer medium bypassed to a common collection line from a common supply line is adjusted to maintain the total flow rate of the heat transfer medium. Therefore, a change in the flow rate of the heat transfer medium supplied to one zone among the plurality of zones does not affect the flow rate of the heat transfer medium supplied to other zones. Hence, in the present embodiment, the independent controllability of the temperatures of the plurality of regions of the substrate located on the plurality of zones is increased.

In the exemplary embodiment, the substrate processing apparatus may include a common supply line, a common collection line, and a plurality of bypass flow rate adjusting valves. The common supply line may be connected to the plurality of common supply pipes. The common collection line may be connected to the plurality of common collection pipes. Each of the plurality of bypass flow rate adjusting valves may be connected between the common supply pipe and the common collection pipe. The common supply pipe may be for the corresponding zone among the plurality of common supply pipes. The common collection pipe may be for the corresponding zone among the plurality of common collection pipes. The controller may adjust a time in which each of the plurality of flow rate adjusting valves is open in alternate opening and closing of each of the plurality of flow rate adjusting valves, and adjusts a time average value of the flow rate of the heat transfer medium supplied to the one or more supply pipes for the corresponding zone of the substrate support stage, among the plurality of supply pipes. The controller may control opening and closing of the plurality of bypass flow rate adjusting valves to maintain the flow rate of the heat transfer medium supplied to each of the plurality of common supply pipes. In the present embodiment, the time average value of the flow rate of the heat transfer medium supplied to each of the plurality of zones is adjusted by adjusting the time average value of the flow rate of the heat transfer medium supplied to the plurality of common supply pipes. Therefore, according to the present embodiment, it is possible to individually control the temperatures of the plurality of regions of the substrate located on the plurality of zones, respectively. In addition, the flow rate of the heat transfer medium supplied to the corresponding common supply pipe is maintained by opening and closing of each of a plurality of bypass flow rate adjusting valves, the change in the flow rate of the heat transfer medium supplied to one zone among the plurality of zones does not affect the flow rate of the heat transfer medium supplied to other zones. Therefore, in the present embodiment, the independent controllability of the temperatures of the plurality of regions of the substrate located on the plurality of zones is increased.

In other exemplary embodiment, substrate processing apparatus is provided. The substrate processing apparatus includes a processing chamber, a substrate support stage, at least one supply pipe, at least one partition, at least one collection pipe, and an actuator. The substrate support stage is disposed in the processing chamber. The substrate support stage includes an upper surface and a lower surface. The upper surface supports a substrate placed thereon. The lower surface is a surface on a side opposite to the upper surface. The substrate support stage provides at least one recess. The at least one recess opens downward. The at least one supply pipe includes an opening end. The opening end opens upward in the at least one recess. The at least one supply pipe is configured to supply a heat transfer medium to the at least one recess. The at least one partition forms at least one space together with the substrate support stage. The at least one space includes the at least one recess. The at least one collection pipe that is configured to collect the heat transfer medium from the at least one space. The actuator is configured to move the at least one supply pipe in order to move the opening end up and down in the at least one recess.

In the above embodiment, the flow velocity of the heat transfer medium flowing in at least one recess is adjusted by moving an opening end of at least one supply pipe up and down in at least one recess. The temperature of the substrate on the substrate support stage changes in accordance with the flow velocity of the heat transfer medium supplied to at least one recess. Therefore, according to the above embodiment, it is possible to control the temperature of the substrate.

In the exemplary embodiment, the substrate support stage may include a plurality of zones. The substrate support stage may provide a plurality of recesses as the at least one recess. The plurality of zones each may include one or more recesses among the plurality of recesses. The substrate processing apparatus may include a plurality of supply pipes as the at least one supply pipe. The opening end of each of the plurality of supply pipes may be disposed in the corresponding recess among the plurality of recesses. The substrate processing apparatus may include a plurality of partitions as the at least one partition. The plurality of partitions may form a plurality of spaces together with the substrate support stage. The plurality of spaces respectively may include the plurality of recesses. The substrate processing apparatus may include a plurality of collection pipes as the at least one collection pipe. The plurality of collection pipes respectively connected to the plurality of spaces. The substrate processing apparatus may include a plurality of common supply pipes and a plurality of common collection pipes. The plurality of common supply pipes each may be connected to one or more supply pipes. The one or more supply pipes may be for the corresponding zone of the substrate support stage, among the plurality of supply pipes. The plurality of common collection pipes, each may be connected to one or more collection pipes for the corresponding zone of the substrate support stage, among the plurality of collection pipes. The actuator may be configured to integrally move one or more supply pipes for the corresponding zone among the plurality of supply pipes. In the present embodiment, the flow velocity of the heat transfer medium is adjusted for each of the plurality of zones of the substrate support stage. Therefore, according to the present embodiment, it is possible to individually control the temperatures of the plurality of regions of the substrate located on each of the plurality of zones.

In exemplary embodiment, the substrate processing apparatus may include a common supply line, a common collection line, a bypass flow rate adjusting valve, and a controller. The common supply line may be connected to the plurality of common supply pipes. The common collection line may be connected to the plurality of common collection pipes. The bypass flow rate adjusting valve may be connected between the common supply line and the common collection line. The controller may be configured to control an opening degree of the bypass flow rate adjusting valve to maintain a total flow rate of the heat transfer medium supplied to the plurality of common supply pipes and the heat transfer medium bypassed to the common collection line from the common supply line. In the present embodiment, even though the position of one or more supply pipes corresponding to one zone is changed, the flow rate of the heat transfer medium bypassed to the common collection line from the common supply line is adjusted to maintain the total flow rate of the heat transfer medium. Therefore, the change in the position of one or more supply pipes corresponding to one zone does not affect the flow rate of the heat transfer medium supplied to the other zones. Hence, in the present embodiment, the independent controllability of the temperatures of the plurality of regions of the substrate located on the plurality of zones is increased.

Hereinafter, various exemplary embodiments will be described. In the drawings, the same or corresponding parts are denoted by the same reference numerals.

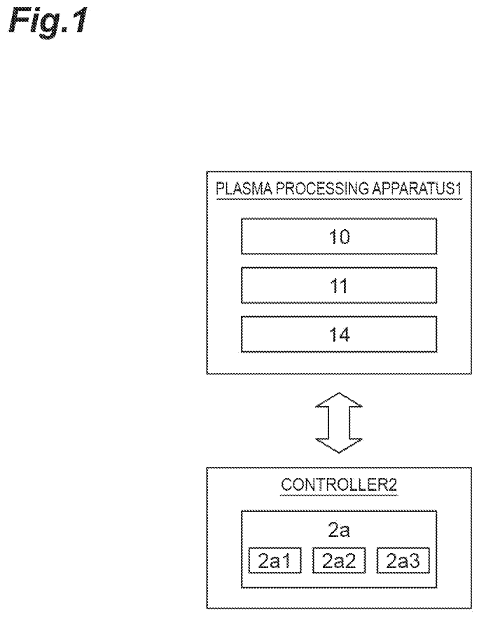

FIG. 1 illustrates an example configuration of a wafer processing system. In an embodiment, the wafer processing system includes a plasma processing apparatus 1 and a controller 2. The plasma processing apparatus 1 is an example substrate processing apparatus, wafer processing system is an example substrate processing system. The plasma processing apparatus 1 includes a processing chamber 10, a substrate support 11, and a plasma generator 14. The processing chamber 10 has a plasma processing space. The processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 14 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

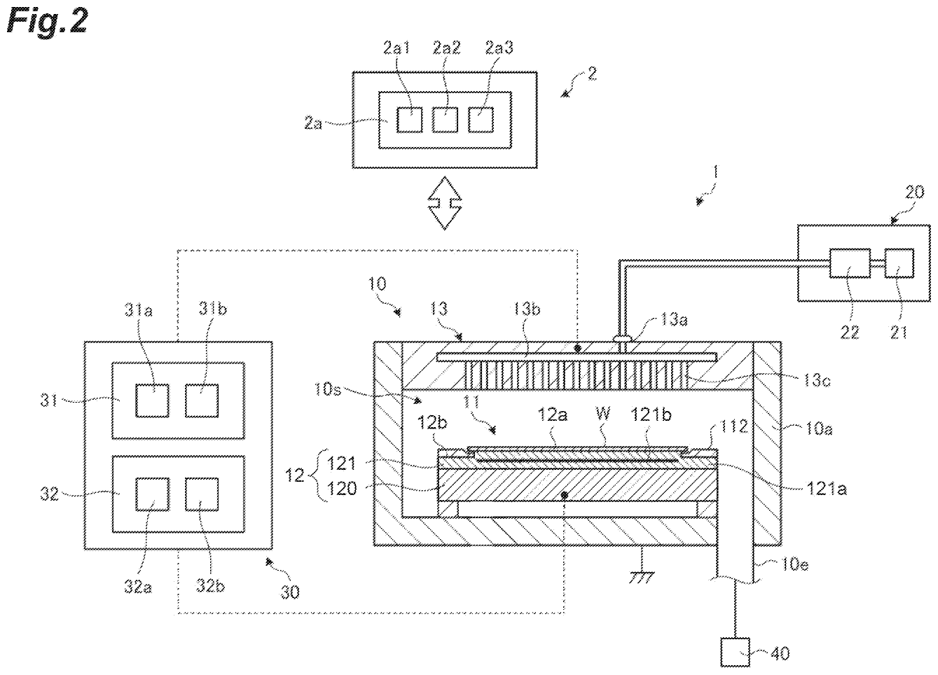

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the processing chamber 10. The gas introduction unit includes a showerhead 13. The substrate support 11 is disposed in a processing chamber 10. The showerhead 13 is disposed above the substrate support 11. In an embodiment, the showerhead 13 functions as at least part of the ceiling of the processing chamber 10. The processing chamber 10 has a plasma processing space 10s that is defined by the showerhead 13, the sidewall 10a of the processing chamber 10, and the substrate support 11. The processing chamber 10 is grounded. The showerhead 13 and the substrate support 11 are electrically insulated from the housing of the processing chamber 10.

The substrate support 11 includes a substrate support stage 12 and a ring assembly 112. The substrate support stage 12 has a central region 12a for supporting a substrate W and an annular region 12b for supporting the ring assembly 112. An example of the substrate W is a wafer. The annular region 12b of the substrate support stage 12 surrounds the central region 12a of the substrate support stage 12 in plan view. The substrate W is disposed on the central region 12a of the substrate support stage 12, and the ring assembly 112 is disposed on the annular region 12b of the substrate support stage 12 so as to surround the substrate W on the central region 12a of the substrate support stage 12. Thus, the central region 12a is also called a substrate supporting surface for supporting the substrate W, while the annular region 12b is also called a ring supporting surface for supporting the ring assembly 112.

In an embodiment, the substrate support stage 12 includes a base 120 and an electrostatic chuck 121. The base 120 includes a conductive member. The conductive member of the base 120 can function as a lower electrode. The electrostatic chuck 121 is disposed on the base 120. The electrostatic chuck 121 includes a ceramic member 121a and an electrostatic electrode 121b disposed in the ceramic member 121a. The ceramic member 121a has the central region 12a. In an embodiment, the ceramic member 121a also has the annular region 12b. Any other member, such as an annular electrostatic chuck or an annular insulting member, surrounding the electrostatic chuck 121 may have the annular region 12b. In this case, the ring assembly 112 may be disposed on either the annular electrostatic chuck or the annular insulating member, or both the electrostatic chuck 121 and the annular insulating member. At least one RF/DC electrode coupled to an RF source 31 and/or a DC source 32 described below may be disposed in the ceramic member 121a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 120 and the at least one RF/DC electrode may each function as a lower electrode. The electrostatic electrode 121b may also be function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply may include a flow modulation device that can modulate or pulse the flow of the at least one process gas.

The electric power source 30 include an RF source 31 coupled to the processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 14. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

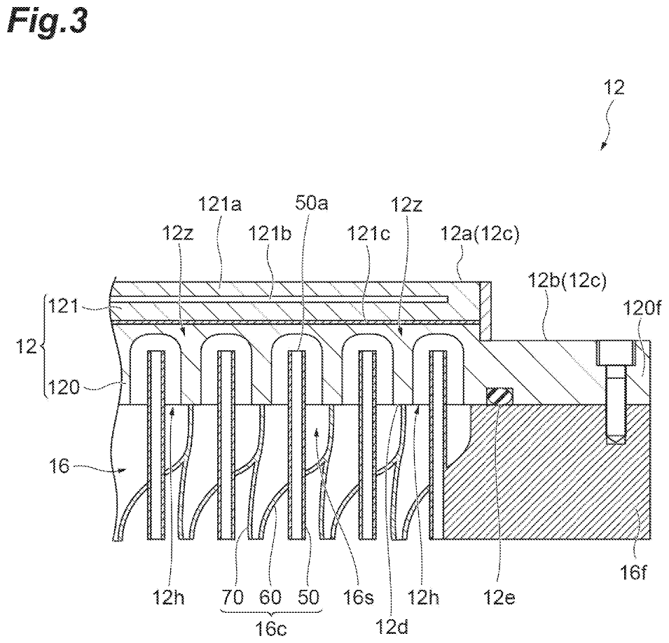

A substrate support stage 12 will be described below in detail with reference to FIG. 3. As described above, the substrate support stage 12 is provided in a processing chamber 10. FIG. 3 is an enlarged cross-sectional view of a portion of a substrate support stage according to the exemplary embodiment.

The substrate support stage 12 has a substantial disk shape. As illustrated in FIG. 3, the substrate support stage 12 includes an upper surface 12c and a lower surface 12d. The upper surface 12c supports a substrate W placed thereon. The upper surface 12c includes a central region 12a and an annular region 12b. In one embodiment, the central region 12a is an upper surface of an electrostatic chuck 121, and the annular region 12b is a peripheral region of an upper surface of a base 120. The lower surface 12d is a surface opposite to the upper surface 12c. In one embodiment, the lower surface 12d is a lower surface of the base 120. The substrate support stage 12 provides at least one recess 12h. At least one recess 12h opens downward. In one embodiment, the substrate support stage 12 provides a plurality of recesses 12h, as the at least one recess 12h. In one embodiment, the plurality of recesses 12h are provided by the base 120.

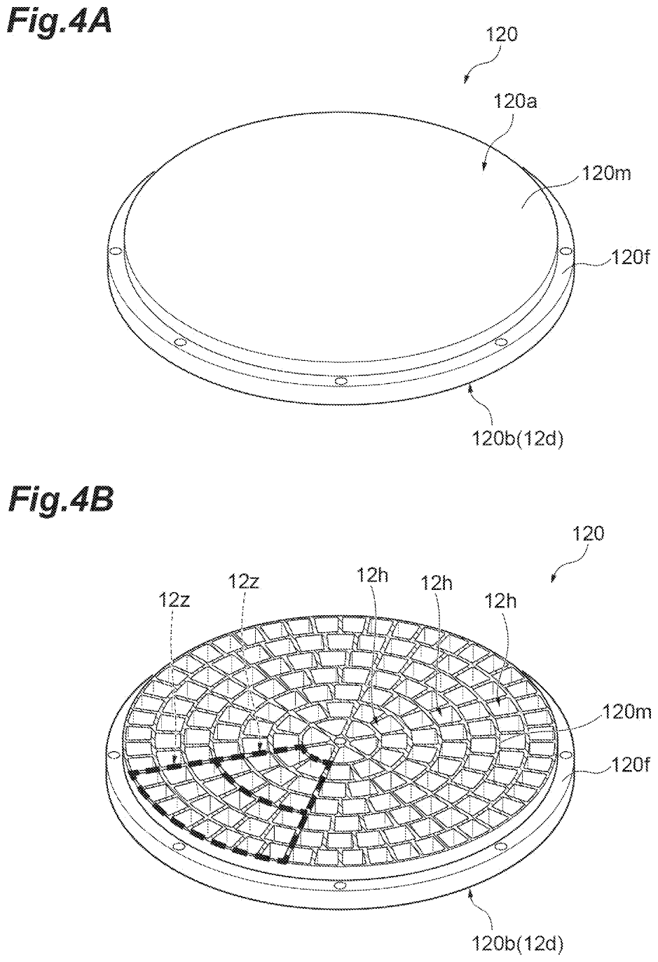

FIG. 4A is a perspective view of the base according to the exemplary embodiment. As illustrated in FIG. 4A, the base 120 has a substantial disk shape, and has a first main surface 120a and a second main surface 120b facing each other. As illustrated in FIG. 3, the electrostatic chuck 121 is bonded to the first main surface 120a of the base 120 through an adhesive layer 121c. The second main surface 120b of the base 120 forms the lower surface 12d of the substrate support stage 12 as illustrated in FIG. 4A.

FIG. 4B is a partially-broken perspective view of the base according to the exemplary embodiment. FIG. 4B illustrates the base 120 in a state that an upper portion including the first main surface 120a is removed. As illustrated in FIGS. 4A and 4B, the base 120 may include a main portion 120m and a flange portion 120f. The main portion 120m is a portion having a substantially circular planar shape. The flange portion 120f is a portion having an annular planar shape. The flange portion 120f is continuous with the main portion 120m to surround an outer periphery of the main portion 120m.

As illustrated in FIG. 4B, the main portion 120m of the base 120 provides the plurality of the recesses 12h described above. The plurality of recesses 12h extend along a thickness direction of the base 120 and open in the second main surface 120b.

Each of the plurality of recesses 12h may have a substantially rectangular planar shape in which the width thereof increases from the center of the base 120 toward the outer side in a plan view. The plurality of recesses 12h are two-dimensionally arranged not to be included in each other. In addition, the planar shape of the plurality of recesses 12h is not limited to the rectangular shape, and may be a circular shape, or a polygonal shape such as a triangular shape or a hexagonal shape.

As illustrated in FIGS. 3 and 4B, the substrate support stage 12 may have a plurality of zones 12z. Each of the plurality of zones 12z may include one or more recesses 12h among the plurality of recesses 12h. As illustrated in FIG. 4B, each of the plurality of zones 12z is disposed in a plurality of regions concentric with the central axis of the substrate support stage 12. The plurality of regions include a circular region including the central axis of the substrate support stage 12 and one or more annular regions outside the circular region. At least one zone among the plurality of zones 12z is disposed in each of the circular region and the one or more annular regions. In one embodiment, the circular region is configured by one zone 12z. In addition, each of the plurality of annular regions is configured by a plurality of zones 12z arranged along the circumferential direction.

The base 120 may be formed of metal. The base 120 may be formed of stainless steel (for example, SUS304). Since stainless steel has a low thermal conductivity, escaping of heat of the electrostatic chuck 121 through the base 120 is prevented. The base 120 may be formed of aluminum. Since aluminum has a low resistivity, it is possible to reduce a power loss in the base 120 in a case where the base 120 is used as a radio frequency electrode.

Return to FIG. 3. As illustrated in FIG. 3, a plasma processing apparatus 1 includes at least one supply pipe 50, at least one partition 60, and at least one collection pipe 70. In one embodiment, the plasma processing apparatus 1 may include a plurality of supply pipes 50 as the at least one supply pipe 50. In one embodiment, the plasma processing apparatus 1 may include a plurality of partitions 60 as the at least one partition 60. In one embodiment, the plasma processing apparatus 1 may include a plurality of collection pipes 70 as the at least one collection pipe 70.

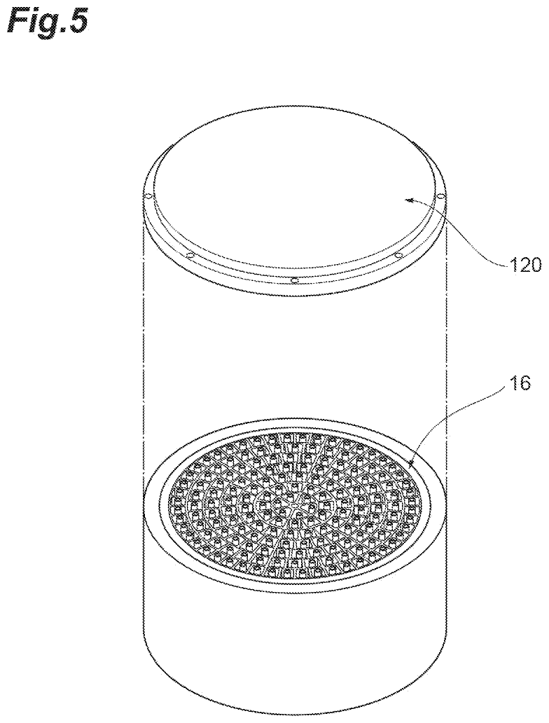

FIG. 5 is an exploded perspective view schematically illustrating the base and a heat exchanger according to the exemplary embodiment. As illustrated in FIG. 5, a substrate support portion 11 may further include a heat exchanger 16. The base 120 may be mounted on the heat exchanger 16. A portion of each of the plurality of supply pipes 50, the plurality of partitions 60, and a portion of each of the plurality of collection pipes 70 may be provided by the heat exchanger 16.

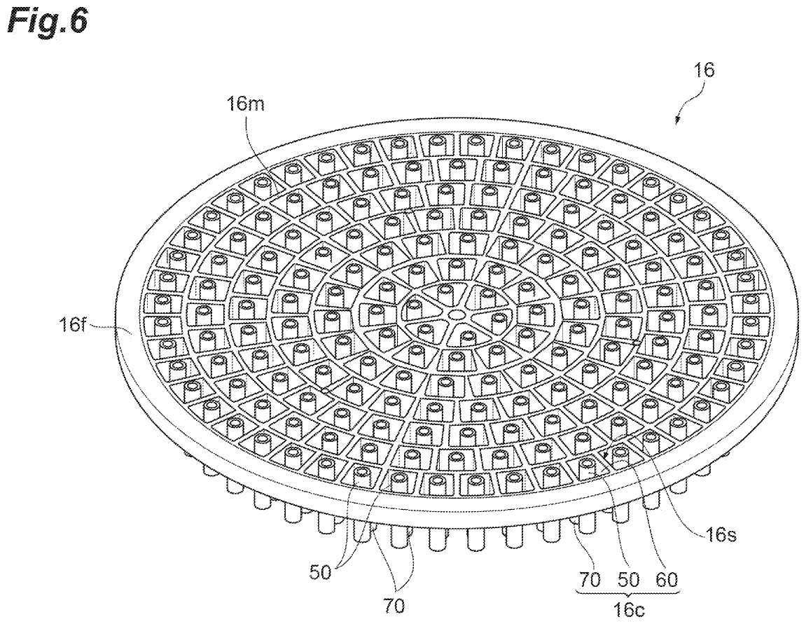

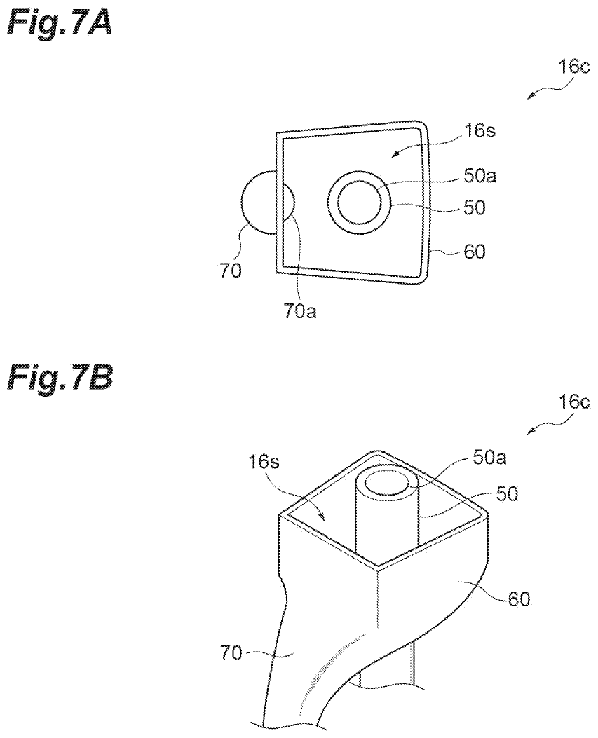

The heat exchanger 16 will be described below with reference to FIGS. 3, 6, and 7. FIG. 6 is a perspective view of the heat exchanger according to the exemplary embodiment. FIG. 7A is a plan view of a cell portion of the heat exchanger as an example, and FIG. 7B is a perspective view of the cell portion of the example heat exchanger as the example.

The heat exchanger 16 may include a main portion 16m and a flange portion 16f. The main portion 16m is a region having a substantially circular planar shape. The flange portion 16f is a region having an annular planar shape, and is continuous with the main portion 16m to surround an outer periphery of the main portion 16m. As illustrated in FIG. 3, the flange portion 120f of the base 120 is disposed on the flange portion 16f of the heat exchanger 16. An O-ring 12e is held between the flange portion 16f and the flange portion 120f. The O-ring 12e seals a gap between the flange portion 16f and the flange portion 120f by being pressed between the flange portion 16f and the flange portion 120f.

The main portion 16m of the heat exchanger 16 provides a plurality of cell portions 16c. The plurality of cell portions 16c are respectively disposed below the plurality of recesses 12h. Each of the plurality of cell portions 16c may have a substantially rectangular planar shape in which the width increases from the center of the heat exchanger 16 toward the outer side in a plan view. Each of the plurality of cell portions 16c provides a substantially rectangular space 16s in a plan view. A plurality of spaces 16s provided by the plurality of cell portions 16c are defined by the partitions 60. In addition, the planar shape of the plurality of cell portions 16c is not limited to a rectangular shape, and may be a circular shape or a polygonal shape such as a triangular shape or a hexagonal shape.

As illustrated in FIGS. 6, FIG. 7A and FIG. 7B, each of the plurality of cell portions 16c includes one of the plurality of supply pipes 50 and one of the plurality of collection pipes 70. In each of the cell portions 16c, the supply pipe 50 extends so that the central axis thereof coincides with the center line of the space 16s. The plurality of supply pipes 50 extend in parallel with each other. Each of the supply pipes 50 includes an opening end 50a. Each of the plurality of supply pipes 50 extends to the opening end 50a thereof toward the corresponding recess 12h among the plurality of recesses 12h. The opening end 50a of each of the plurality of supply pipes 50 is disposed in the corresponding recess 12h among the plurality of recesses 12h. The opening end 50a opens upward in the corresponding recess 12h. At least one supply pipe 50 is configured to supply a heat transfer medium to at least one recess 12h. In one embodiment, the plurality of supply pipes 50 are configured to supply the heat transfer medium to the plurality of recesses 12h, respectively.

As illustrated in FIG. 3, in each cell portion 16c, at least one partition 60 forms at least one space 16s together with the substrate support stage 12. The space 16s includes the recess 12h. The plurality of partitions 60 form the plurality of spaces 16s together with the substrate support stage 12. The plurality of spaces 16s include a plurality of the recesses 12h, respectively. Each of the plurality of partitions 60 is connected to the second main surface 120b of the base 120 to communicate with the recess 12h corresponding to each of the plurality of partitions 60 among the plurality of recesses 12h. Each of the plurality of partitions 60 surrounds an outer peripheral surface of the supply pipe 50 to provide the space 16s around the outer peripheral surface of the supply pipe 50.

As illustrated in FIG. 7A, each of the plurality of collection pipes 70 includes an opening end 70a. In each cell portion 16c, the opening end 70a of the collection pipe 70 is connected to the partition 60 so that the flow path of the collection pipe 70 communicates with the bottom portion of the space 16s. That is, the plurality of collection pipes 70 communicate with the plurality of recesses 12h through the spaces 16s, respectively. The plurality of collection pipes 70 are connected to the plurality of spaces 16s, respectively. At least one collection pipe 70 is configured to collect the heat transfer medium from at least one space 16s. In one embodiment, the plurality of collection pipes 70 are configured to collect the heat transfer medium from the plurality of spaces 16s, respectively.

The heat exchanger 16 may be formed of resin, ceramic, or a material containing metal as the main component. The heat exchanger 16 may be formed of a material having a low thermal conductivity, for example, ceramic or resin, in order to suppress the effect of the adjacent cell portions 16c. The heat exchanger 16 may be partially formed of a different material in order to partially change the strength and/or the thermal conductivity of the heat exchanger 16. The heat exchanger 16 may be formed of the same material as the base 120. The base 120 and the heat exchanger 16 may be integrally formed by using, for example, a 3D printer.

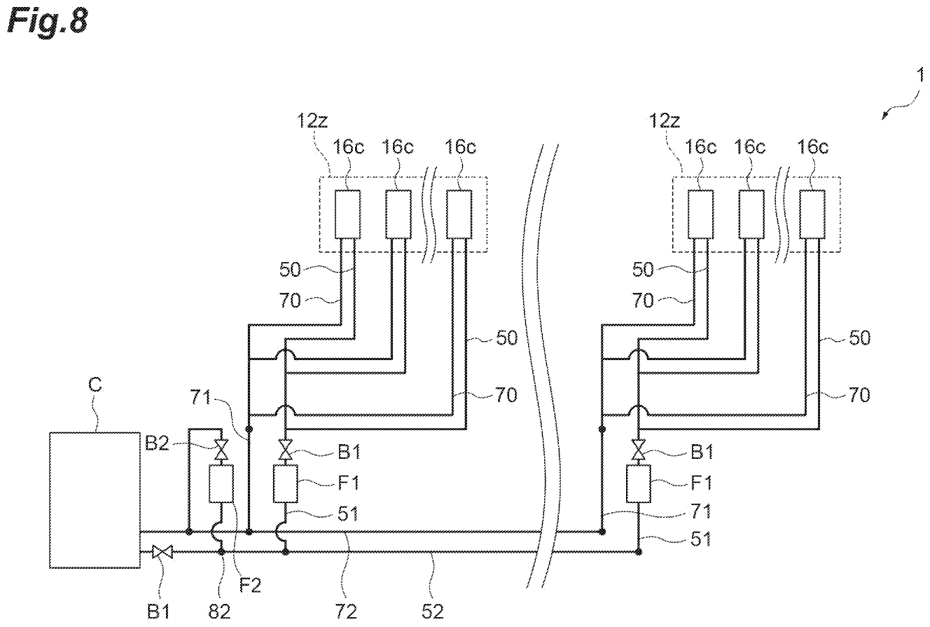

The description will be made below with reference to FIG. 8. FIG. 8 is a diagram schematically illustrating a circulation supply system of the heat transfer medium in the substrate processing apparatus according to the exemplary embodiment. The at least one supply pipe 50 and the at least one collection pipe 70 are connected to a circulation device C of the heat transfer medium. For example, the circulation device C is a chiller. The circulation device C adjusts the temperature of the heat transfer medium. The circulation device is disposed outside the processing chamber 10. The heat transfer medium is supplied from the circulation device C to at least one supply pipe 50. The heat transfer medium supplied from at least one supply pipe 50 to at least one recess 12h is collected by at least one collection pipe 70 (see FIG. 3). The heat transfer medium collected by the collection pipe 70 is brought back to the circulation device C.

The plasma processing apparatus 1 includes at least one flow rate adjusting valve B1. The flow rate adjusting valve B1 is connected to at least one supply pipe 50. A controller 2 controls an opening degree of the flow rate adjusting valve B1 to adjust the flow rate of the heat transfer medium supplied to at least one supply pipe 50. As an example, the flow rate adjusting valve B1 is an electromagnetic valve. The plasma processing apparatus 1 may include at least one flow meter F1. The flow meter F1 is connected to at least one supply pipe 50. For example, the controller 2 controls the opening degree of the flow rate adjusting valve B1 based on information on the flow rate obtained from the flow meter F1.

In the plasma processing apparatus 1, the flow velocity of a heat transfer medium supplied to at least one recess 12h of the substrate support stage 12 is adjusted by adjusting the flow rate of the heat transfer medium supplied to at least one supply pipe 50. The temperature of a substrate W on the substrate support stage 12 changes in accordance with the flow velocity of the heat transfer medium supplied to at least one recess 12h. Therefore, according to the plasma processing apparatus 1, it is possible to control the temperature of the substrate W.

In one embodiment, the plasma processing apparatus 1 may include a plurality of flow rate adjusting valves B1 as at least one flow rate adjusting valve B1. In one embodiment, the plasma processing apparatus 1 may further include a plurality of common supply pipes 51 and a plurality of common collection pipes 71. The plasma processing apparatus 1 may further include a plurality of flow meters F1 as at least one flow meter F1.

The plurality of common supply pipes 51 are connected between the circulation device C and the corresponding flow rate adjusting valve B1 among the plurality of flow rate adjusting valves B1. Each of the plurality of common supply pipes 51 is connected to one or more supply pipes 50 through the corresponding flow rate adjusting valve B1 among the plurality of flow rate adjusting valves B1. The one or more supply pipes 50 are supply pipes 50 for the corresponding zone 12z of the substrate support stage 12 among the plurality of supply pipes 50. The plurality of common collection pipes 71 are connected to the circulation device C. Each of the plurality of common collection pipes 71 is connected to one or more collection pipes 70 among the plurality of collection pipes 70. The one or more collection pipes 70 are collection pipes for the corresponding zone 12z of the substrate support stage 12 among the plurality of collection pipes 70. The plurality of flow meters F1 measure the flow rate of the heat transfer medium flowing through the plurality of common supply pipes 51. The controller 2 may control the opening degree of the corresponding flow rate adjusting valve B1 based on the information on the flow rate obtained from each of the plurality of flow meters F1. In the present embodiment, the flow velocity of the heat transfer medium is adjusted for each of the plurality of zones 12z of the substrate support stage 12. Therefore, it is possible to individually control the temperatures of the plurality of regions of the substrate W located on each of the plurality of zones 12z.

In one embodiment, the plasma processing apparatus 1 may include a common supply line 52, a common collection line 72, and a bypass flow rate adjusting valve B2. The common supply line 52 is connected to a plurality of common supply pipes 51. The common supply line 52 is connected between the circulation device C and each of the plurality of common supply pipes 51. The common collection line 72 is connected to a plurality of common collection pipes 71. The common collection line 72 is connected between the circulation device C and each of the plurality of common collection pipes 71. The bypass flow rate adjusting valve B2 is connected between the common supply line 52 and the common collection line 72. That is, a bypass flow path 82 including the bypass flow rate adjusting valve B2 is connected between the common supply line 52 and the common collection line 72. As an example, the bypass flow rate adjusting valve B2 is an electromagnetic valve. A flow meter F2 may be disposed in the bypass flow path 82.

Each of the plurality of flow rate adjusting valves B1 is configured to adjust the flow rate of the heat transfer medium supplied to the one or more supply pipes 50 by adjusting the opening degree thereof. The one or more supply pipes 50 are supply pipes 50 for the corresponding zone 12z of the substrate support stage 12 among the plurality of supply pipes 50. The controller 2 is configured to control the opening degree of each of the plurality of flow rate adjusting valves B1, and to control the opening degree of the bypass flow rate adjusting valve B2 to maintain the total flow rate of the heat transfer medium supplied to the plurality of common supply pipes 51. For example, the controller 2 adjusts the opening degree of each of the plurality of flow rate adjusting valves B1 and the opening degree of the bypass flow rate adjusting valve B2 based on the information on the flow rate obtained from each of the plurality of flow meters F1 and the flow meter F2. In the present embodiment, even though the flow rate of the heat transfer medium supplied to one zone among the plurality of zones 12z is changed, the flow rate of the heat transfer medium bypassed to the common collection line 72 from the common supply line 52 is adjusted to maintain the total flow rate of the heat transfer medium. Therefore, a change in the flow rate of the heat transfer medium supplied to one zone among the plurality of zones 12z does not affect on the flow rate of the heat transfer medium supplied to other zones. Therefore, in the present embodiment, the independent controllability of the temperatures of the plurality of regions of the substrate W located on the plurality of zones 12z is increased.

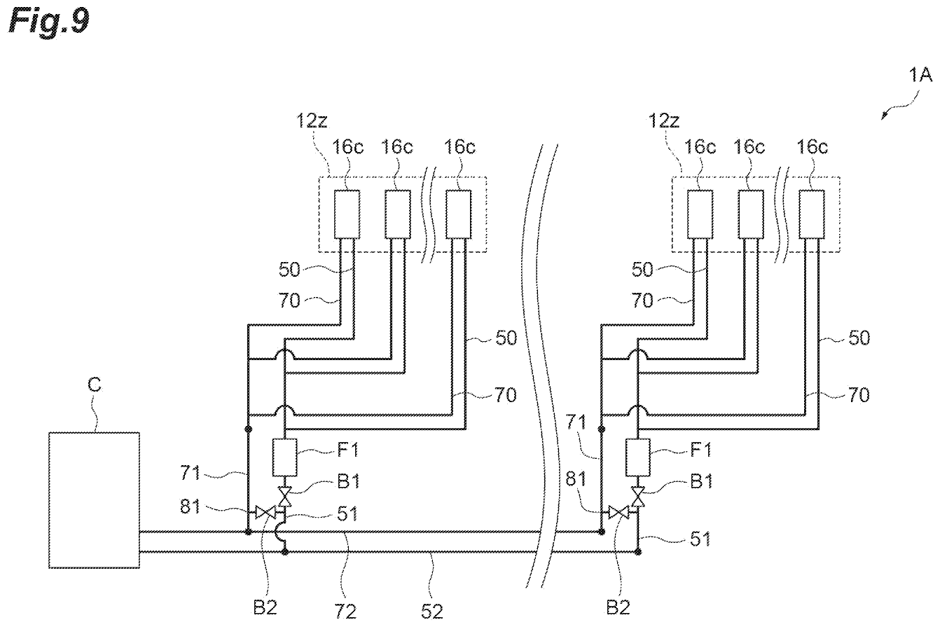

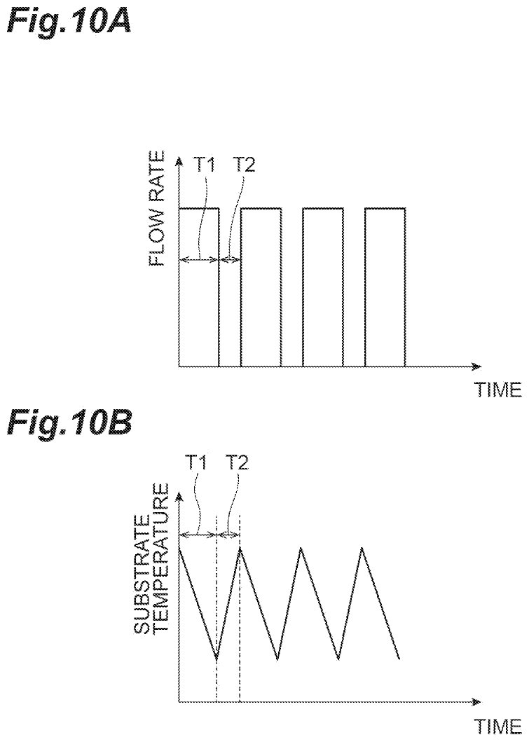

The description will be made below with reference to FIGS. 9, FIG. 10A and FIG. 10B. FIG. 9 is a diagram schematically illustrating a circulation supply system of a heat transfer medium in a substrate processing apparatus according to another exemplary embodiment. FIG. 10A is a graph showing an example of a relationship between the time and the flow rate of the heat transfer medium in the embodiment of FIG. 9. FIG. 10B is a graph showing an example of a relationship between the time and the temperature of the substrate in the embodiment of FIG. 9. Differences of the embodiment of FIG. 9 from the embodiment of FIG. 8 will be described below.

A plasma processing apparatus 1A illustrated in FIG. 9 is another example of the substrate processing apparatus. The plasma processing apparatus 1A includes a plurality of bypass flow rate adjusting valves B2. Each of the plurality of bypass flow rate adjusting valves B2 is connected between the common supply pipe 51 and the common collection pipe 71 for the corresponding zone 12z. The controller 2 controls the alternate opening and closing of each of the plurality of flow rate adjusting valves B1 and the plurality of bypass flow rate adjusting valves B2.

As illustrated in FIGS. 10A and 10B, in a period T1 in which each of the plurality of flow rate adjusting valves B1 is opened, the heat transfer medium is supplied to one or more supply pipes 50 in the corresponding zone 12z, and the temperature of a region in the substrate W on the zone 12z is lowered. In the period T1, the corresponding bypass flow rate adjusting valve B2 is closed.

On the other hand, in a period T2 in which each of the plurality of flow rate adjusting valves B1 is closed, the supply of the heat transfer medium to the one or more supply pipes 50 in the corresponding zone 12z is stopped, and the temperature of the region in the substrate W on the zone 12z increases. In the period T2, the bypass flow rate adjusting valve B2 is opened to maintain the flow rate of the heat transfer medium supplied to the common supply pipe 51.

When the sum of the period T1 and the period T2 is set to one cycle, the one cycle in the present embodiment is, for example, 1 second to 0.05 seconds (1 Hz to 20 Hz). Further, when a value (T1/T1+T2) obtained by dividing the period T1 by the sum of the period T1 and the period T2 is used as the Duty ratio, the Duty ratio in the present embodiment is, for example, 0.1 to 0.8. As a result, it is possible to suppress the amount of fluctuation in the temperature of the region in the substrate W on the zone 12z corresponding to each of the plurality of flow rate adjusting valves B1 to be within 2° C.

The controller 2 adjusts a time length of the period T1 in which each of the plurality of flow rate adjusting valves B1 is opened in the alternate opening and closing of each of the plurality of flow rate adjusting valves B1, and adjusts the time average value of the flow rate of the heat transfer medium supplied to the one or more supply pipes 50 in the corresponding zone 12z. As a result, the time average value of the temperature of the region in the substrate W on the corresponding zone 12z is adjusted.

Therefore, according to the plasma processing apparatus 1A, it is possible to individually control the temperatures of the plurality of regions of the substrate W located on each of the plurality of zones 12z. In addition, the flow rate of the heat transfer medium supplied to the corresponding common supply pipe 51 is maintained by opening and closing of each of the plurality of bypass flow rate adjusting valves B2. Therefore, a change in the flow rate of the heat transfer medium supplied to one zone among the plurality of zones 12z does not affect the flow rate of the heat transfer medium supplied to other zones. Therefore, in the plasma processing apparatus 1A, the independent controllability of the temperatures of the plurality of regions of the substrate W located on the plurality of zones 12z is increased.

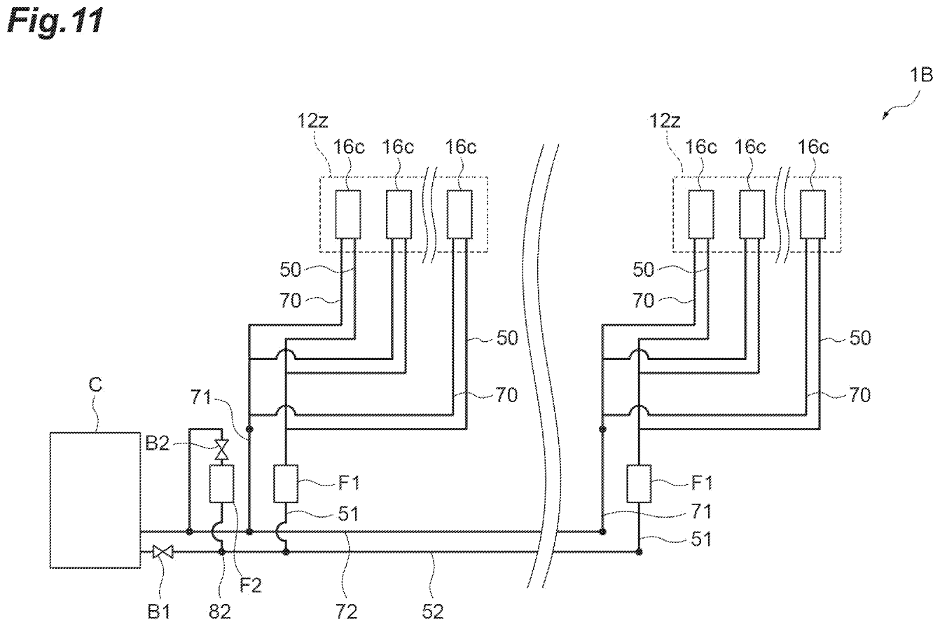

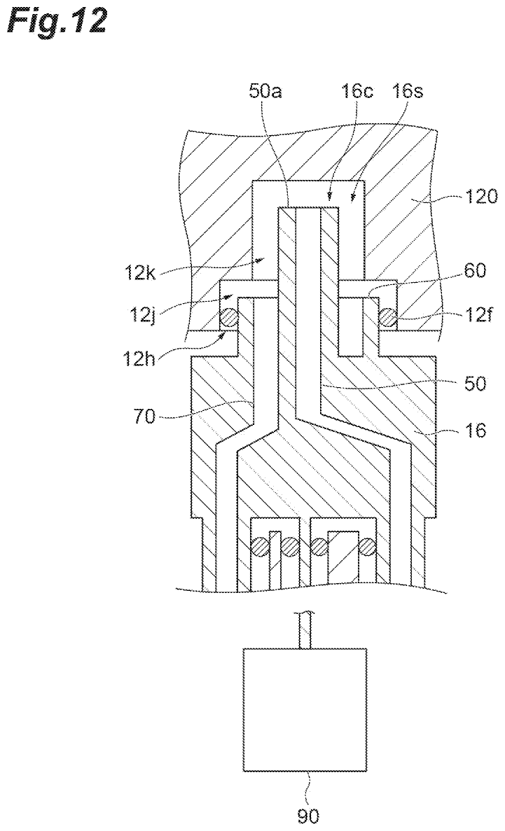

The description will be made below with reference to FIGS. 11 and 12. FIG. 11 is a diagram schematically illustrating a circulation supply system of a heat transfer medium in a substrate processing apparatus according to still another exemplary embodiment. FIG. 12 is an enlarged cross-sectional view of a portion of a substrate support stage according to still another exemplary embodiment. Differences of the embodiment of FIG. 11 from the embodiment of FIG. 8 will be described below.

A plasma processing apparatus 1B illustrated in FIG. 11 is still another example of the substrate processing apparatus. The plasma processing apparatus 1B does not include the flow rate adjusting valve B1. As illustrated in FIG. 12, the plasma processing apparatus 1B includes an actuator 90. The actuator 90 may be, for example, a unit in which a motor and a ball screw are combined. The actuator 90 is configured to move the supply pipe 50 in order to move the opening end 50a up and down in the recess 12h. In one embodiment, the actuator 90 may be configured to integrally move one or more supply pipes 50. The one or more supply pipes 50 are supply pipes 50 for the corresponding zone among the plurality of supply pipes 50.

In one embodiment, the actuator 90 moves one or more cell portions 16c included in the corresponding zone up and down. Each of the plurality of recesses 12h is configured by an upper portion 12k in which the corresponding opening end 50a is located therein, and a lower portion 12j in which the partition 60 is located therein. An O-ring 12f is disposed between an outer periphery of the partition 60 and a surface defining the lower portion 12j.

In the plasma processing apparatus 1B, the flow velocity of the heat transfer medium flowing in each of the plurality of recesses 12h is adjusted by moving the opening end 50a of the corresponding supply pipe 50 up and down. The temperature of a substrate W on the substrate support stage 12 changes in accordance with the flow velocity of the heat transfer medium supplied to each of the plurality of recesses 12h. Therefore, according to the above embodiment, it is possible to control the temperature of the substrate W.

In one embodiment, the actuator 90 integrally moves one or more supply pipes 50 for the corresponding zone 12z among the plurality of supply pipes 50. In the present embodiment, the flow velocity of the heat transfer medium is adjusted for each of the plurality of zones 12z of the substrate support stage 12. Therefore, according to the present embodiment, it is possible to individually control the temperatures of the plurality of regions of the substrate W located on each of the plurality of zones 12z.

In one embodiment, the controller 2 may be configured to control the opening degree of the bypass flow rate adjusting valve B2 to maintain the total flow rate of the heat transfer medium supplied to the plurality of common supply pipes 51 and the heat transfer medium bypassed to the common collection line 72 from the common supply line 52. In the present embodiment, even though the position of one or more supply pipes 50 corresponding to one zone 12z is changed, the flow rate of the heat transfer medium bypassed to the common collection line 72 from the common supply line 52 is adjusted to maintain the total flow rate of the heat transfer medium. Therefore, the change in the position of one or more supply pipes 50 corresponding to one zone 12z does not affect the flow rate of the heat transfer medium supplied to the other zones. Therefore, in the present embodiment, the independent controllability of the temperatures of the plurality of regions of the substrate W located on the plurality of zones 12z is increased.

Although the various exemplary embodiments have been described above, various additions, omissions, substitutions, and changes may be made without being limited to the exemplary embodiments described above. In addition, elements from different embodiments can be combined to form other embodiments.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the aspects following claims.

What is claimed is:

1. A substrate processing apparatus comprising:
a processing chamber;
a substrate support stage that is disposed in the processing chamber, includes an upper surface that supports a substrate placed thereon and a lower surface on a side opposite to the upper surface, and provides at least one recess that opens downward;
at least one supply pipe that includes an opening end that opens upward in the at least one recess and is configured to supply a heat transfer medium to the at least one recess;
at least one partition that forms at least one space including the at least one recess together with the substrate support stage;
at least one collection pipe that is configured to collect the heat transfer medium from the at least one space;
at least one flow rate adjusting valve that is connected to the at least one supply pipe; and
a controller that is configured to control the at least one flow rate adjusting valve to adjust a flow rate of the heat transfer medium supplied to the at least one supply pipe.

2. The substrate processing apparatus according to claim 1, wherein
the substrate support stage provides a plurality of recesses as the at least one recess, and includes a plurality of zones, each including one or more of the plurality of recesses,
the substrate processing apparatus includes a plurality of supply pipes as the at least one supply pipe,
the opening end of each of the plurality of supply pipes is disposed in a corresponding recess among the plurality of recesses,
the substrate processing apparatus includes, as the at least one partition, a plurality of partitions that form a plurality of spaces respectively including the plurality of recesses, together with the substrate support stage,
the substrate processing apparatus includes, as the at least one collection pipe, a plurality of collection pipes respectively connected to the plurality of spaces,
the substrate processing apparatus includes a plurality of flow rate adjusting valves as the at least one flow rate adjusting valve,
the substrate processing apparatus further comprises:
a plurality of common supply pipes, each connected to one or more supply pipes for a corresponding zone of the substrate support stage, among the plurality of supply pipes through a corresponding flow rate adjusting valve among the plurality of flow rate adjusting valves; and
a plurality of common collection pipes, each connected to one or more collection pipes for a corresponding zone of the substrate support stage, among the plurality of collection pipes.

3. The substrate processing apparatus according to claim 2, further comprising:
a common supply line connected to the plurality of common supply pipes;
a common collection line connected to the plurality of common collection pipes; and
a bypass flow rate adjusting valve connected between the common supply line and the common collection line,
wherein each of the plurality of flow rate adjusting valves is configured to adjust the flow rate of the heat transfer medium supplied to the one or more supply pipes for the corresponding zone of the substrate support stage, among the plurality of supply pipes by adjusting an opening degree thereof, and
the controller is configured to
control the opening degree of each of the plurality of flow rate adjusting valves, and
control an opening degree of the bypass flow rate adjusting valve to maintain a total flow rate of the heat transfer medium supplied to the plurality of common supply pipes and the heat transfer medium bypassed to the common collection line from the common supply line.

4. The substrate processing apparatus according to claim 2, further comprising:
a common supply line connected to the plurality of common supply pipes;
a common collection line connected to the plurality of common collection pipes; and
a plurality of bypass flow rate adjusting valves,
wherein each of the plurality of bypass flow rate adjusting valves is connected between the common supply pipe for the corresponding zone among the plurality of common supply pipes and the common collection pipe for the corresponding zone among the plurality of common collection pipes, and
the controller
adjusts a time in which each of the plurality of flow rate adjusting valves is open in alternate opening and closing of each of the plurality of flow rate adjusting valves, and adjusts a time average value of the flow rate of the heat transfer medium supplied to the one or more supply pipes for the corresponding zone of the substrate support stage, among the plurality of supply pipes, and
controls opening and closing of the plurality of bypass flow rate adjusting valves to maintain the flow rate of the heat transfer medium supplied to each of the plurality of common supply pipes.

5. A substrate processing apparatus comprising:
a processing chamber;
a substrate support stage that is disposed in the processing chamber, includes an upper surface that supports a substrate placed thereon and a lower surface on a side opposite to the upper surface, and provides at least one recess that opens downward;
at least one supply pipe that includes an opening end that opens upward in the at least one recess and is configured to supply a heat transfer medium to the at least one recess;
at least one partition that forms at least one space including the at least one recess together with the substrate support stage;
at least one collection pipe that is configured to collect the heat transfer medium from the at least one space; and
an actuator that is configured to move the at least one supply pipe in order to move the opening end up and down in the at least one recess.

6. The substrate processing apparatus according to claim 5, wherein
the substrate support stage provides a plurality of recesses as the at least one recess, and includes a plurality of zones each including one or more recesses among the plurality of recesses,
the substrate processing apparatus includes a plurality of supply pipes as the at least one supply pipe,
the opening end of each of the plurality of supply pipes is disposed in a corresponding recess among the plurality of recesses,
the substrate processing apparatus includes, as the at least one partition, a plurality of partitions that form a plurality of spaces respectively including the plurality of recesses, together with the substrate support stage,
the substrate processing apparatus includes, as the at least one collection pipe, a plurality of collection pipes respectively connected to the plurality of spaces,
the substrate processing apparatus further comprises:
a plurality of common supply pipes, each connected to one or more supply pipes for a corresponding zone of the substrate support stage, among the plurality of supply pipes; and
a plurality of common collection pipes, each connected to one or more collection pipes for the corresponding zone of the substrate support stage, among the plurality of collection pipes, and
the actuator is configured to integrally move one or more supply pipes for the corresponding zone among the plurality of supply pipes.

7. The substrate processing apparatus according to claim 6, further comprising:
a common supply line connected to the plurality of common supply pipes;
a common collection line connected to the plurality of common collection pipes;
a bypass flow rate adjusting valve connected between the common supply line and the common collection line; and
a controller configured to control an opening degree of the bypass flow rate adjusting valve to maintain a total flow rate of the heat transfer medium supplied to the plurality of common supply pipes and the heat transfer medium bypassed to the common collection line from the common supply line.
